(19) United States
(12) Patent Application Publication
(10) Pub. No.: US 2010/0295115 A1
(43) Pub. Date: Nov. 25, 2010

(54) NONVOLATILE SEMICONDUCTOR MEMORY DEVICE INCLUDING NONVOLATILE MEMORY CELL

(76) Inventor: Kikuko SUGIMAE, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/783,888

(22) Filed: May 20, 2010

(30) Foreign Application Priority Data
May 22, 2009 (JP) 2009-124415

(51) Int. Cl. H01L 27/115; H01L 21/8246

(52) U.S. Cl. 257/324; 438/591; 257/E21.679; 257/E27.103; 257/E29.309

(57) ABSTRACT

A nonvolatile semiconductor memory device includes the following structure. Element isolation films are formed at predetermined intervals in a first direction in a surface region of a semiconductor substrate. The element isolation films extend in a second direction and isolate the surface region of the semiconductor substrate to provide element regions. Upper surface of the element isolation films are lower than upper surface of the element regions of the semiconductor substrate. A tunnel insulating film is formed on the element region. A charge accumulation layer is formed only on the tunnel insulating film. A block layer continuously is formed in the first direction on the charge accumulation layer and the element isolation film. A bottom surface of the block layer on the element isolation film is lower than the upper surface of the element region of the semiconductor substrate. A gate electrode is formed on the block layer.

### CROSS-REFERENCE TO RELATED APPLICATIONS

This application is based upon and claims the benefit of priority from prior Japanese Patent Application No. 2009-124415, filed May 22, 2009, the entire contents of which are incorporated herein by reference.

### BACKGROUND OF THE INVENTION

1. Field of the Invention

The present invention relates a nonvolatile semiconductor memory device including a nonvolatile memory cell and relates to a nonvolatile semiconductor memory device having, for example, a MONOS structure.

2. Description of the Related Art

In a conventional nonvolatile semiconductor memory device having a MONOS structure, a sectional structure along a WL direction is as follows. A plurality of element regions AA are formed by an element isolation insulating film, for example, shallow trench isolation (STI) formed between silicon semiconductor substrates. The element isolation insulating films are arranged at predetermined intervals in a word-line direction. On the element regions AA, a tunnel insulating film and a charge accumulation layer are formed (for example, see Jpn. Pat. Appln. KOKAI Publication No. 2002-26153).

In this case, an upper surface of the charge accumulation layer and an upper surface of the element isolation insulating film are arranged at almost the same level. On the charge accumulation layer and the element isolation insulating layer, block layers are continuously formed. On the block layers, a control gate configured by a metal electrode and a silicide layer is formed.

However, in the structure mentioned above, the level of the upper surface of the element isolation insulating film and the level of the upper surface of the charge accumulation layer cannot be easily adjusted to each other. Since the upper surface of the element isolation insulating film moves vertically from the upper surface of the charge accumulation layer, a coupling ratio of memory cells varies disadvantageously.

### BRIEF SUMMARY OF THE INVENTION

According to a first aspect of the present invention, there is provided a nonvolatile semiconductor memory device comprising: a semiconductor substrate; element isolation insulating films formed at predetermined intervals in a first direction in a surface region of the semiconductor substrate, the element isolation insulating films extending in a second direction orthogonal to the first direction, isolating the surface region of the semiconductor substrate to provide element regions, and upper surface of the element isolation insulating films being lower than upper surface of the element regions of the semiconductor substrate; a tunnel insulating film formed on the element region; a charge accumulation layer formed only on the tunnel insulating film; a block layer continuously formed in the first direction on the charge accumulation layer and the element isolation insulating film, a bottom surface of the block layer on the element isolation insulating film is lower than the upper surface of the element region of the semiconductor substrate; and a gate electrode formed on the block layer.

According to a second aspect of the present invention, there is provided a nonvolatile semiconductor memory device comprising: a semiconductor substrate; element isolation insulating films formed at predetermined intervals in a first direction in a surface region of the semiconductor substrate, the element isolation insulating films extending in a second direction orthogonal to the first direction, isolating the surface region of the semiconductor substrate to provide element regions, and upper surface of the element isolation insulating films being lower than upper surface of the element regions of the semiconductor substrate; a tunnel insulating film which covers an upper surface and a side surface of the element region; a charge accumulation layer formed on the tunnel insulating film; a block layer continuously formed in the first direction on the charge accumulation layer and the element isolation insulating film, a bottom surface of the block layer on the element isolation insulating film being lower than the upper surface of the element region of the semiconductor substrate; and a gate electrode formed on the block layer.

According to a third aspect of the present invention, there is provided a method of manufacturing a nonvolatile semiconductor memory device, comprising: forming a tunnel insulating film on a semiconductor substrate; forming a charge accumulation layer on the tunnel insulating film; removing the charge accumulation layer, the tunnel insulating film, and an upper layer portion of the semiconductor substrate, to form a trench extending in a first direction; forming an element isolation insulating film in the trench to arrange an element region on the semiconductor substrate; removing an upper layer portion of the element isolation insulating film to make an upper surface of the element isolation insulating film lower than an upper surface of the element region of the semiconductor substrate; forming a block layer on the charge accumulation layer and the element isolation insulating film; and forming a gate electrode on the block layer.

### BRIEF DESCRIPTION OF THE SEVERAL VIEWS OF THE DRAWING

FIG. 1 is a plan view showing a configuration of a nonvolatile semiconductor memory device according to a first embodiment of the present invention;

FIG. 2 is a sectional view along line 2-2 in FIG. 1;

FIG. 3 is a sectional view along line 3-3 in FIG. 1;

FIGS. 4A and 4B are graphs showing electric field intensities obtained when a predetermined voltage is applied across a gate electrode and an element region in the nonvolatile semiconductor memory device according to the first embodiment;

FIG. 5 is a sectional view along line 2-2 in FIG. 1 in a nonvolatile semiconductor memory device according to a second embodiment;

FIG. 6 is a sectional view along line 3-3 in FIG. 1 in the nonvolatile semiconductor memory device according to the second embodiment;

FIGS. 7A and 7B are graphs showing electric field intensities obtained when a predetermined voltage is applied across a gate electrode and an element region in the nonvolatile semiconductor memory device according to the second embodiment;

FIG. 8 is a sectional view showing a method of manufacturing a nonvolatile semiconductor memory device according to the first embodiment;

FIG. 9 is a sectional view showing the method of manufacturing according to the first embodiment;

FIG. 10 is a sectional view showing the method of manufacturing according to the first embodiment;

FIG. 11 is a sectional view showing the method of manufacturing according to the first embodiment;

FIG. 12 is a sectional view showing a method of manufacturing a nonvolatile semiconductor memory device according to the second embodiment;

FIG. 13 is a sectional view showing the method of manufacturing according to the second embodiment; and

FIG. 14 is a sectional view showing the method of manufacturing according to the second embodiment.

### DETAILED DESCRIPTION OF THE INVENTION

Embodiments of the present invention will be described below with reference to the accompanying drawings. The same reference numbers denote the same parts, respectively, throughout all the drawings.

### First Embodiment

A nonvolatile semiconductor memory device according to a first embodiment of the present invention will be described.

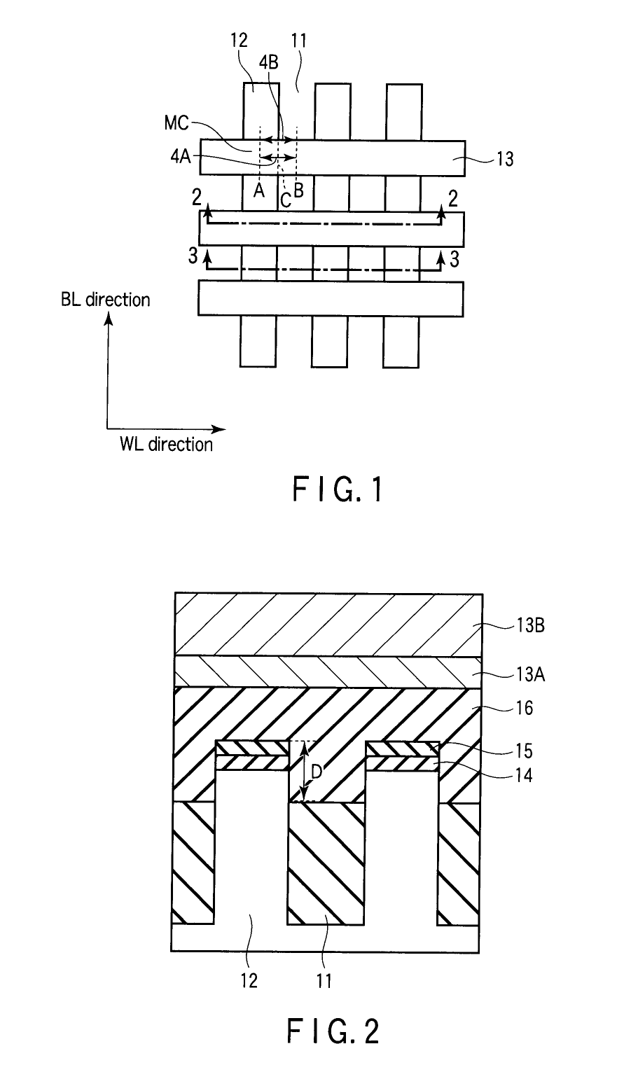

FIG. 1 is a plan view showing a configuration of the nonvolatile semiconductor memory device according to the first embodiment.

As shown in the drawing, in a surface region of a silicon semiconductor substrate, element isolation insulating films (for example, ST1) 11 extending in a bit-line (BL) direction (second direction) orthogonal to a word-line (WL) direction (first direction) are disposed at predetermined intervals in the WL direction. The element isolation insulating films 11 isolate the surface region of the semiconductor substrate to form a plurality of element regions 12. Gate electrodes 13 extending in the WL direction are disposed at predetermined intervals in the BL direction. Memory cells MC are formed at crossing points between the element regions 12 and the gate electrodes 13, respectively. More specifically, the memory cells MC are arranged in the form of a matrix on the semiconductor substrate.

FIG. 2 is a sectional view along line 2-2 in FIG. 1. This sectional view shows a section on a word line in the WL direction.

As shown in FIG. 2, on the silicon semiconductor substrate in the element region 12, a tunnel insulating film 14 is disposed, and a charge accumulation layer 15 is disposed on the tunnel insulating film 14. On the charge accumulation layer 15, a block layer 16 is disposed. Furthermore, on the block layer 16, a metal layer 13A is disposed, and a silicide layer 13B is disposed on the metal layer 13A. The metal layer 13A and the silicide layer 13B configure the gate electrode 13.

On the element isolation insulating film 11, the block layer 16 is disposed. The block layer 16 on the element isolation insulating film 11 is arranged to be sandwiched between the semiconductor substrates of the adjacent element regions 12.

Furthermore, on the block layer 16, the metal layer 13A is disposed. On the metal layer 13A, the silicide layer 13B is disposed. The block layer 16, the metal layer 13A, and the silicide layer 13B are continuously disposed in the first direction on the charge accumulation layer 15 and the element isolation insulating film 11.

In the structure shown in FIG. 2, an upper surface of the element isolation insulating film 11 is lower than an upper surface of the semiconductor substrate in the element region 12. In other words, a bottom surface of the block layer 16 on the element isolation insulating film 11 is lower than the upper surface of the semiconductor substrate. The block layer 16 is in contact with a side surface of the element region 12. The block layer 16 is disposed sequentially with the element regions 12 and the element isolation insulating films 11, and an upper surface of the block layer 16 is flat. Furthermore, the charge accumulation layer 15 is disposed on only the tunnel insulating film 14. The side surfaces of the tunnel insulating film 14 and the charge accumulation layer 15 are in contact with the block layer 16.

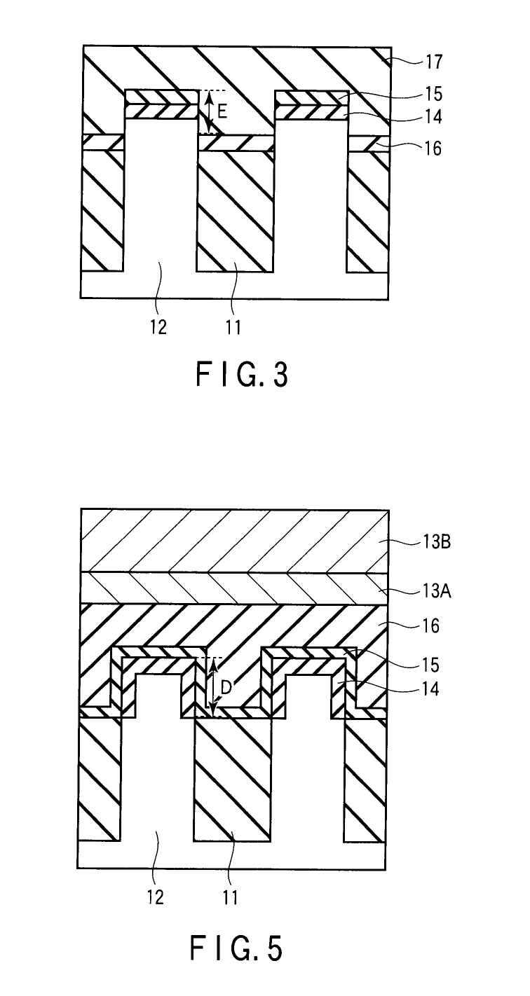

FIG. 3 is a sectional view along line 3-3 in FIG. 1. This sectional view shows a section on a region which does not include a word line between the word lines (gate electrodes) in the WL direction.

As shown in FIG. 3, the tunnel insulating film 14 is disposed on the semiconductor substrate in the element region 12, and the charge accumulation layer 15 is disposed on the tunnel insulating film 14. An insulating interlayer 17, for example, a silicon oxide film is disposed on the charge accumulation layer 15.

On the element isolation insulating film 11, the block layer 16 is disposed. The block layer 16 on the element isolation insulating film 11 is arranged to be sandwiched between the semiconductor substrates of the adjacent element regions 12. The upper surface of the block layer 16 is lower than the upper surface (a lower surface of the tunnel insulating film 14) of the semiconductor substrate in the element region 12. Furthermore, on the block layer 16, the insulating interlayer 17 is disposed.

As shown in FIG. 3, even on a section along the WL direction in a region in which a gate electrode is not disposed, the upper surface of the element isolation insulating film 11 is lower than the upper surface (the lower surface of the tunnel insulating film 14) of the semiconductor substrate in the element region 12. The insulating interlayer 17 is in contact with a side surface of the element region 12.

The element isolation insulating film 11 and the tunnel insulating film 14 are formed of, for example, silicon oxide films, and the charge accumulation layer 15 is formed of, for example, a silicon nitride film. The block layer 16 is formed of a high-dielectric-constant (high-k) film essentially consisting of, for example, aluminum oxide (Al₂O₃). The silicide layer 13B essentially consists of, for example, nickel silicide (NiSi), titanium silicide (TiSi), and tungsten silicide (WSi).

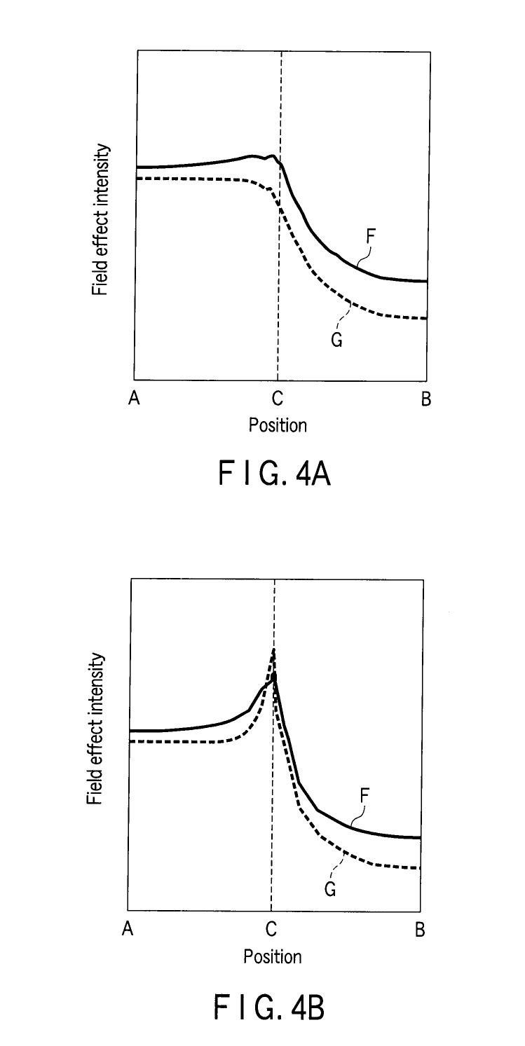

In this case, FIGS. 4A and 4B show simulation results of field intensities obtained in case a distance D shown in FIG. 2 and a distance E shown in FIG. 3 are changed and in case a predetermined voltage is applied across a gate electrode and the element region 12. In this case, distance D is a distance from the upper surface of the charge accumulation layer 15 under the gate electrode to the upper surface of the element isolation insulating film 11, and distance E is a distance from the upper surface of the charge accumulation layer 15 in a region which does not include the word line to the upper surface of the block layer 16. Note that an in-house simulator is used in the simulation.

FIG. 4A shows a field intensity of a portion (center portion of the gate electrode 13) along a line passing through points A, C and B, indicated by 4A in FIG. 1, and FIG. 4B shows a field intensity of a portion (boundary portion of the gate electrode 13) along a line passing through points A to B indicated by 4B in FIG. 1. Point A is a center point of a gate electrode in the WL direction, point B is a center point of the element isolation insulating film 11 in the WL direction, and point C is a boundary portion between the element region 12 and the element isolation insulating film 11.

A field intensity obtained in case of both distances D and E are zero (conventional art) is represented by F, and a field intensity obtained in case of at least distance D of distances D and E is a predetermined distance (first embodiment) is represented by G. In case distances D and E are greater than zero, even though distances D and E are changed, the simulation results are rarely different from each other. Therefore, for practical purposes, a result at only one point at which distance D is the predetermined distance is shown as a typical example.

As is apparent from FIGS. 4A and 4B, even though the upper surface of the element isolation insulating film 11 is made lower than a surface (the lower surface of the tunnel insulating film 14) of the semiconductor substrate (indicated by G), a field intensity almost equal to that obtained in case distances D and E are set to zero, i.e., in case the upper surface of the element isolation insulating film 11 is set level with or higher than the surface of the semiconductor substrate (indicated by F) is obtained. More specifically, a field intensity obtained in case the upper surface of the element isolation insulating film 11 is set lower than the surface of the semiconductor substrate is not largely different from that obtained in case the upper surface of the element isolation insulating film 11 is set level with or higher than the surface of the semiconductor substrate.

In this case, the upper surface of the element isolation insulating film 11 is higher than the surface (the lower surface of the tunnel insulating film 14) of the semiconductor substrate, the upper surface of the element isolation insulating film 11 changes depending on a variation in processing. As a result, the coupling ratio of a memory cells varies. On the other hand, the upper surface of the element isolation insulating film 11 is set lower than the upper surface (the lower surface of the tunnel insulating film 14) of the semiconductor substrate. As a result, it is possible to suppress the coupling ratio of the memory cells. In this case, the degree to which the upper surface of the element isolation insulating film 11 is set lower than the upper surface (the lower surface of the tunnel insulating film 14) of the semiconductor substrate is defined as DP. DP is greater than the degree of change of the upper surface of the element isolation insulating film 11 by the variation.

On the other hand, electric fields applied in a programming state and an erasing state are not considerably different from those in the conventional art, and the program and erase characteristics are not degraded. In particular, a field, shown in FIG. 4B, in the boundary portion between the element region 12 and the element isolation insulating film 11 across which the highest electric field is applied in program and erase states in the first embodiment is almost equal to that in the conventional art.

In FIG. 3, the block layer 16 is left on the element isolation insulating film 11. It is possible to prevent the upper surface of the element isolation insulating film 11 from being etched in an etching step of the gate electrode. As a result, variation in the coupling ratio of the memory cells can be further suppressed.

### Second Embodiment

A nonvolatile semiconductor memory device according to a second embodiment of the present invention will now be described. The same reference numbers as in the first embodiment denote the same parts in the second embodiment.

FIG. 5 is a sectional view along line 2-2 in FIG. 1 in the nonvolatile semiconductor memory device according to the second embodiment. The second embodiment is different from the first embodiment in that the tunnel insulating film 14 is disposed to cover a surface of the element region 12 upwardly projecting from the element isolation insulating film 11.

As shown in FIG. 5, on the semiconductor substrate in the element region 12, the tunnel insulating film 14 is disposed in such a manner as to cover the element region 12 projecting from a portion between the element isolation insulating films 11, on the semiconductor substrate in the element region 12. This structure can be manufactured such that, after the element isolation insulating film 11 is formed, the tunnel insulating film 14 is formed on the projected element region 12 by thermal oxidation. On the tunnel insulating film 14, the charge accumulation layer 15 is formed to cover the tunnel insulating film 14. On the charge accumulation layer 15, the block layer 16 is formed. Furthermore, on the block layer 16, the metal layer 13A is formed, and the silicide layer 13B is formed on the metal layer 13A.

On the element isolation insulating films 11, the charge accumulation layer 15 is disposed. The charge accumulation layer 15 is disposed sequentially with the tunnel insulating film 14 and the element isolation insulating film 11 in the WL direction. On the charge accumulation layer 15 on the element isolation insulating film 11, the block layer 16 is disposed. The block layer 16 on the element isolation insulating film 11 is arranged to be sandwiched between the semiconductor substrates of the adjacent element regions 12. Furthermore, the metal layer 13A is disposed on the block layer 16 on the element isolation insulating films 11, and the silicide layer 13B is disposed on the metal layer 13A. The block layer 16, the metal layer 13A, and the silicide layer 13B are continuously formed on the element regions 12 and the element isolation insulating films 11 in a word-line (WL) direction (first direction).

In the structure shown in FIG. 5, the upper surface of the element isolation insulating films 11 is lower than the upper surface of the semiconductor substrate in the element region 12. In other words, the bottom surface of the block layer 16 on the element isolation insulating film 11 is lower than the upper surface of the semiconductor substrate in the element region 12. A side surface of the element isolation insulating film 11 is in contact with the block layer 16 through the tunnel insulating film 14 and the charge accumulation layer 15. Furthermore, the charge accumulation layer 15 is disposed sequentially with the tunnel insulating film 14 and the element isolation insulating film 11 in the WL direction.

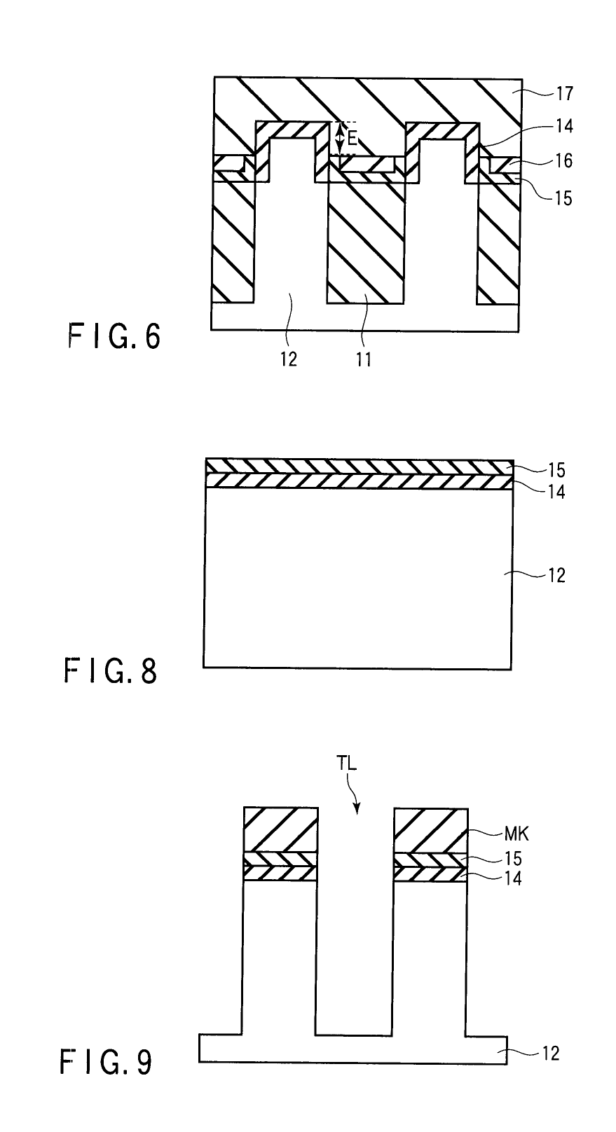

FIG. 6 is a sectional view along line 3-3 in FIG. 1 in the second embodiment. The sectional view shows a section on a region which does not include a word line between word lines (gate electrodes) in the WL direction. Even on the section along a WL direction in a region in which a gate electrode is not disposed, the upper surface of the element isolation insulating film 11 is lower than the upper surface (the lower surface of the tunnel insulating film 14) of the semiconductor substrate in the element region 12.

As shown in FIG. 6, on the semiconductor substrate in the element region 12, the tunnel insulating film 14 is disposed to cover the element regions 12 projecting from a portion between the element isolation insulating films 11 is disposed. On the tunnel insulating film 14, the insulating interlayer 17 is disposed.

The charge accumulation layer 15 is disposed on the element isolation insulating film 11, and the block layer 16 is disposed on the charge accumulation layer 15. The block layer 16 on the element isolation insulating film 11 is arranged to be sandwiched between the semiconductor substrates of the adjacent element regions 12. The upper surface of the block layer 16 is lower than the upper surface (the lower surface of the tunnel insulating film 14) of the semiconductor substrate in the element regions 12. Furthermore, the insulating interlayer film 17 is disposed on the block layer 16.

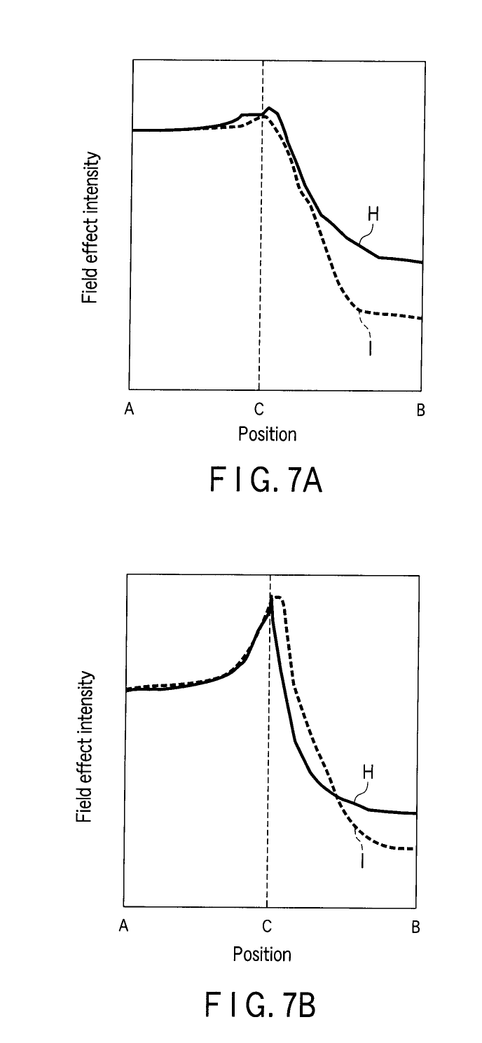

FIGS. 7A and 7B show simulation results of field intensities obtained in case distance D shown in FIG. 5 and distance E shown in FIG. 6 are changed and when a predetermined voltage is applied across the gate electrode and the element region 12. Note that an in-house simulator is used in the simulation. FIG. 7A shows a field intensity of a portion (center portion of the gate electrode 13) along a line passing through points A, C and B, indicated by 4A in FIG. 1, and FIG. 7B shows a field intensity of a portion (boundary portion of the gate electrode 13) along a line passing through points A, C and B, indicated by 4B in FIG. 1. Point A is a center point of the gate electrode in the WL direction, point B is a center point of the element isolation insulating film 11 in the WL direction, and point C is a boundary portion between the element region 12 and the element isolation insulating film 11.

A field intensity obtained in case both distances D and E are zero (conventional art) is represented by H, and a field intensity obtained in case at least distance D of distances D and E is a predetermined distance (second embodiment) is represented by I. In case distances D and E are greater than zero, even though distances D and E are changed, the simulation results are rarely different from each other. Therefore, for practical purposes, a result at only one point at which distance D is the predetermined distance is shown as a typical example. At the field intensity I of the second embodiment, a field intensity of the portion of the charge accumulation layer 15 is not shown to simplify comparison with the conventional art.

As is apparent from FIGS. 7A and 7B, even though the upper surface of the element isolation insulating film 11 is made lower than the surface (the lower surface of the tunnel insulating film 14) of the semiconductor substrate (indicated by I), a field intensity almost equal to that obtained in case distances D and E are set to zero, i.e., in case the upper surface of the element isolation insulating film 11 is set level with or higher than the surface of the semiconductor substrate (indicated by H) is obtained. More specifically, a field intensity obtained in case the upper surface of the element isolation insulating film 11 is set lower than the surface of the semiconductor substrate is not considerably different from that obtained in case the upper surface of the element isolation insulating film 11 is set level with or higher than the surface of the semiconductor substrate (indicated by H). More specifically, a field intensity obtained in case the upper surface of the element isolation insulating film 11 is set lower than the upper surface of the semiconductor substrate is not largely different from that obtained in case the upper surface of the element isolation insulating film 11 is set level with or higher than the upper surface of the semiconductor substrate.

In this case, the upper surface of the element isolation insulating film 11 is higher than the upper surface (the lower surface of the tunnel insulating film 14) of the semiconductor substrate, the upper surface of the element isolation insulating film 11 changes depending on a variation in processing. As a result, the coupling ratio of a memory cells varies. On the other hand, the upper surface (the lower surface of the tunnel insulating film 14) of the element isolation insulating film 11 is set lower than the upper surface (the lower surface of the tunnel insulating film 14) of the semiconductor substrate. As a result, it is possible to suppress the coupling ratio of the memory cell. In this case, the degree to which the upper surface of the element isolation insulating film 11 is set lower than the upper surface (the lower surface of the tunnel insulating film 14) of the semiconductor substrate is defined as DP. DP is preferably greater than the degree of change of the upper surface of the element isolation insulating film 11 by the variation.

On the other hand, electric fields applied in the programming state and the erasing state are not considerably different from those in the conventional art, and the program and erase characteristics are not degraded. In particular, a field in the boundary portion between the element region 12 and the element isolation insulating film 11 across which the highest electric field is applied in programming and erasing states in the second embodiment, shown in FIG. 7B, is almost equal to that in the conventional art.

In FIG. 6, the charge accumulation layer 15 and the block layer 16 are left on the element isolation insulating film 11. It is possible to prevent the upper surface of the element isolation insulating film 11 from being etched in an etching step of the gate electrode. As a result, variation in control gate coupling ratio of the memory cells can be further suppressed.

As shown in FIG. 5, since the block layer 16 is disposed to cover the tunnel insulating film 14 and the charge accumulation layer 15, a field can be efficiently applied to the tunnel insulating film 14. The area of the charge accumulation layer 15 can be made greater than that in the first embodiment, and the number of electrons accumulated in the charge accumulation layer 15 can be increased.

### Third Embodiment

A third embodiment is a method of manufacturing a nonvolatile semiconductor memory device according to the first embodiment. FIGS. 8 to 11 partway show manufacturing steps in the method of manufacturing the semiconductor memory device shown in FIGS. 2 and 3. FIGS. 8 to 11 are sectional views along lines 2-2 and 3-3 in FIG. 1. These sections have the same structures up to the middle of the manufacturing steps.

As shown in FIG. 8, an impurity is injected into the upper surface of the silicon semiconductor substrate (element region) 12 to form an N-type well (not shown) on an upper layer portion of the silicon substrate 12. Injection of an impurity serving as channel implantation is formed a P-type well (not shown) on a part of the upper layer portion of the N-type well. The tunnel insulating film 14 is formed on the silicon substrate 12. A silicon nitride (SiN) is deposited on the tunnel insulating film 14 to have a thickness of, for example, 5 nm in order to form the charge accumulation layer 15.

As shown in FIG. 9, a mask material MK is formed on the charge accumulation layer 15. The mask material MK is constituted by a laminate film essentially consisting of silicon oxide, amorphous silicon, and silicon nitride. The mask material MK is selectively removed by a lithography technique. The charge accumulation layer 15, the tunnel insulating film 14, and the upper layer portion of the silicon substrate 12 are selectively removed by using the mask material MK as a mask. In this manner, a plurality of trenches TL linearly extending in the BL direction (memory string direction) are formed.

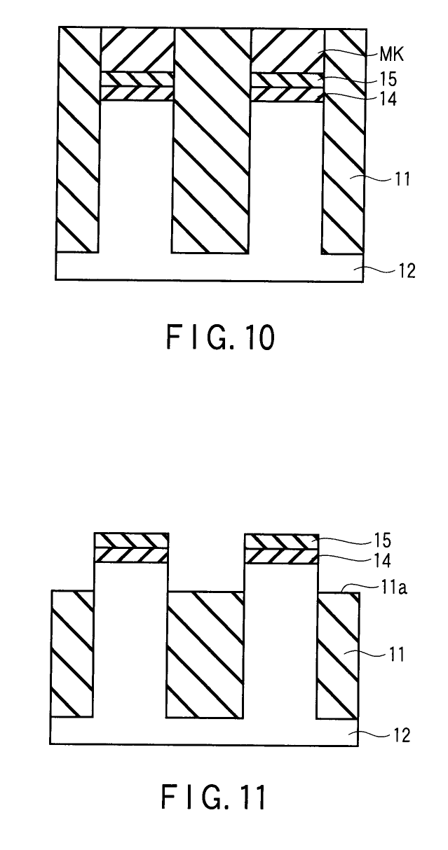

As shown in FIG. 10, a silicon oxide is deposited on the structure shown in FIG. 9, i.e., the entire surface of the silicon substrate 12 to bury the trenches TL. Thereafter, chemical mechanical polishing (CMP) is performed by using the mask material MK as a stopper to remove the silicon oxide deposited on the mask material MK. In this manner, the silicon oxide is left in only the trenches TL to form the element isolation insulating films 11. As a result, the charge accumulation layer 15 and the tunnel insulating film 14 are isolated from each other along the BL direction, and the silicon substrate is partitioned into the plurality of element regions 12 extending in the BL direction. At this time, the upper surface of the element isolation insulating film 11 is nearly level with the upper surface of the mask material MK.

As shown in FIG. 11, dry etching is performed to remove an upper portion of the element isolation insulating film 11 in order to lower an upper surface 11a. At this time, the upper surface 11a of the element isolation insulating film 11 is kept lower than the upper surface of the silicon substrate 12. In this case, in consideration of a variation in processing, processing conditions are set such that the upper surface 11a of the element isolation insulating film 11 is lower than the upper surface of the silicon substrate 12 at almost all the positions in the silicon substrate 12. Thereafter, the mask material MK is removed.

By using a known manufacturing method, the block layer (insulating layer) 16, the metal layer 13A, and a polysilicon film are formed. The block layer 16, the charge accumulation layer 15, and the tunnel insulating film 14 are selectively removed by a lithography technique to isolate the block layer 16, the charge accumulation layer 15, and the tunnel insulating film 14 along the WL direction. In this manner, the gate electrode 13 extending in the WL direction is formed. At this time, the film thickness of the block layer 16 on the element isolation insulating film 11 is greater than the film thickness of the block layer 16 on the element region because the upper surface of the element isolation insulating film 11 is lower than the upper surface of the silicon substrate 12. As a result, the block layer 16 on the element isolation insulating film 11 is left without being removed to prevent the upper surface of the element isolation insulating film 11 from being lowered. A diffusion layer of the memory cell transistor is formed, and the insulating interlayer 17 is deposited on the entire surface of the silicon substrate 12 to make it possible to manufacture the nonvolatile semiconductor memory device according to the first embodiment.

### Fourth Embodiment

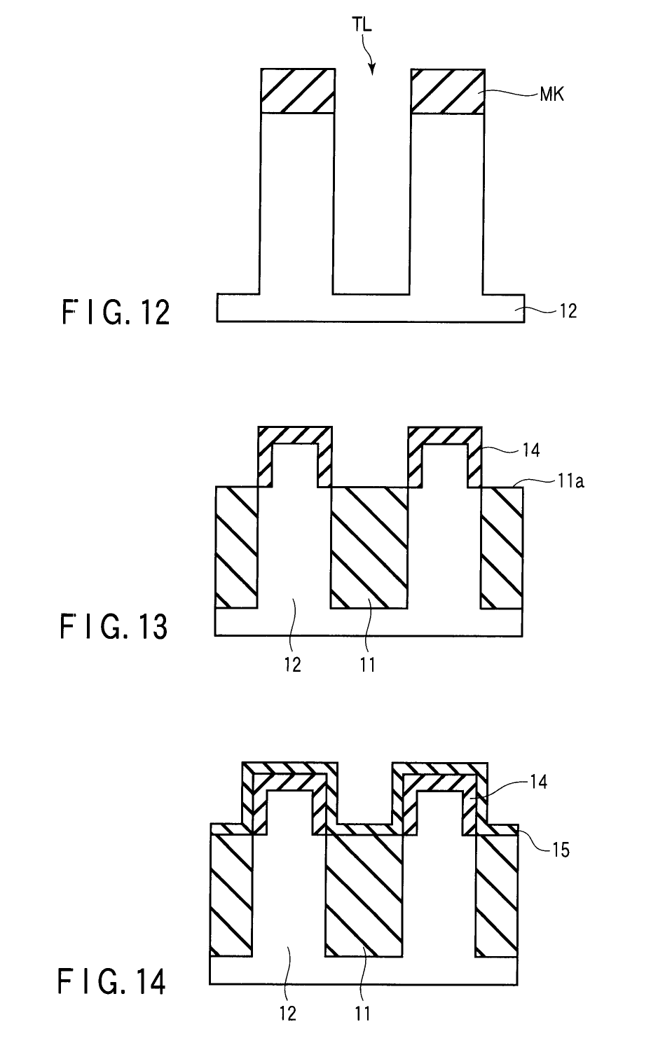

A fourth embodiment is a method of manufacturing a nonvolatile semiconductor memory device according to the second embodiment. FIGS. 12 to 14 partway show manufacturing steps in the method of manufacturing the semiconductor memory device shown in FIGS. 5 and 6. FIGS. 12 to 14 are sectional views along lines 2-2 and 3-3 in FIG. 1. These sections have the same structures up to the middle of the manufacturing steps.

An impurity is injected into the upper surface of the silicon semiconductor substrate 12 to form an N-type well (not shown) on an upper layer portion of the silicon substrate 12. Injection of an impurity serving as channel implantation is formed a P-type well (not shown) on a part of the upper layer portion of the N-type well.

As shown in FIG. 12, the mask material MK is formed on the element regions 12. The mask material MK is composed of, for example, silicon nitride. The mask material MK is selectively removed by a lithography technique. The upper portion of the silicon substrate 12 is selectively removed by using the mask material MK as a mask. In this manner, the plurality of trenches TL linearly extending in the BL direction (memory string direction) are formed.

A silicon oxide is deposited on the structure shown in FIG. 12, i.e., the entire surface of the silicon substrate 12 to bury the trenches TL. Thereafter, CMP is performed by using the mask material MK as a stopper to remove the silicon oxide deposited on the mask material MK. In this manner, the silicon oxide is left only in the trenches TL to form the element isolation insulating films 11. As a result, the silicon substrate 12 is partitioned into the plurality of element regions 12 extending in the BL direction. At this time, the upper surface of the element isolation insulating film 11 is nearly level with the upper surface of the mask material MK.

As shown in FIG. 13, dry etching is performed to remove an upper layer portion of the element isolation insulating film 11 in order to lower an upper surface 11a. At this time, the upper surface 11a of the element isolation insulating film 11 is kept lower than the upper surface of the silicon substrate 12. In this case, in consideration of a variation in processing, processing conditions are set such that the upper surface 11a of the element isolation insulating film 11 is lower than the upper surface of the silicon substrate 12 at almost all the positions in the silicon substrate 12. Thereafter, the mask material MK is removed.

The tunnel insulating film 14 is formed by a thermal oxidation method using the element isolation insulating film 11 as a mask. As a result, as shown in FIG. 13, the tunnel insulating film 14 is formed on a surface portion of the element region 12 exposed from the element isolation insulating film 11.

As shown in FIG. 14, the charge accumulation layer 15 is deposited on the silicon substrate 12, i.e., on the tunnel insulating film 14 and the element isolation insulating film 11. The subsequent steps will not be described because the steps are the same as those in the third embodiment. The nonvolatile semiconductor memory device is manufactured in the aforementioned manner.

According to the embodiments of the present invention, a nonvolatile semiconductor memory device in which a variation in control gate coupling ratio of memory cells can be provided.

The embodiments described above can be singularly executed, and the embodiments can also be executed in arbitrary combination with each other. Furthermore, the embodiments described above include inventions in various phases. When the plurality of constituent elements described in the embodiments are arbitrarily combined, inventions in the various phases can also be extracted.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
a semiconductor substrate;
element isolation insulating films disposed at predetermined intervals in a first direction in a surface region of the semiconductor substrate, the element isolation insulating films extending in a second direction orthogonal to the first direction, isolating the surface region of the semiconductor substrate to provide element regions, and an upper surface of the element isolation insulating films being lower than an upper surface of the element regions of the semiconductor substrate;
a tunnel insulating film disposed on the element region;
a charge accumulation layer disposed on the tunnel insulating film;
a block layer continuously disposed in the first direction on the charge accumulation layer and the element isolation insulating film, a bottom surface of the block layer on the element isolation insulating film is lower than the upper surface of the element regions of the semiconductor substrate; and
a gate electrode disposed on the block layer.

2. The nonvolatile semiconductor memory device according to claim 1,
wherein an upper surface of the block layer is flat on the charge accumulation layer and the element isolation insulating film.

3. The nonvolatile semiconductor memory device according to claim 2,
wherein the block layer is arranged between the element regions in the first direction.

4. The nonvolatile semiconductor memory device according to claim 1,
wherein each of memory cells comprises the charge accumulation layer, the block layer, and the gate electrode, and the memory cells are arranged at predetermined intervals in the second direction, and
the block layer is arranged on the element isolation insulating film between the gate electrodes in the second direction.

5. The nonvolatile semiconductor memory device according to claim 4,
wherein the upper surface of the block layer arranged on the element isolation insulating film between the gate electrodes in the second direction is lower than the upper surface of the element region.

6. A nonvolatile semiconductor memory device comprising:
a semiconductor substrate;
element isolation insulating films disposed at predetermined intervals in a first direction in a surface region of the semiconductor substrate, the element isolation insulating films extending in a second direction orthogonal to the first direction, isolating the surface region of the semiconductor substrate to provide element regions, and an upper surface of the element isolation insulating films being lower than an upper surface of the element regions of the semiconductor substrate;
a tunnel insulating film which covers an upper surface and a side surface of the element region;
a charge accumulation layer disposed on the tunnel insulating film;
a block layer continuously disposed in the first direction on the charge accumulation layer and the element isolation insulating film, a bottom surface of the block layer on the element isolation insulating film being lower than the upper surface of the element region of the semiconductor substrate; and
a gate electrode disposed on the block layer.

7. The nonvolatile semiconductor memory device according to claim 6,
wherein the charge accumulation layer is continuously disposed in the first direction on the tunnel insulating film and the element isolation insulating film.

8. The nonvolatile semiconductor memory device according to claim 6,
wherein an upper surface of the block layer is flat on the element region and the element isolation insulating film.

9. The nonvolatile semiconductor memory device according to claim 8,
wherein the block layer is arranged between the element regions in the first direction.

10. The nonvolatile semiconductor memory device according to claim 6,
wherein each of memory cells comprises the tunnel insulating film, the charge accumulation layer, the block layer, and the gate electrode, and the memory cells are arranged at predetermined intervals in the second direction, and
the block layer is arranged on the element isolation insulating film between the gate electrodes in the second direction.

11. The nonvolatile semiconductor memory device according to claim 10,
wherein the upper surface of the block layer arranged on the element isolation insulating film between the gate electrodes in the second direction is lower than the upper surface of the element region.

12. The nonvolatile semiconductor memory device according to claim 6,
wherein the charge accumulation layer comprises a concave portion on the element isolation insulating film between the gate electrodes in the second direction,
the block layer is provided in the concave portion of the charge accumulation layer.

13. The nonvolatile semiconductor memory device according to claim 12,
wherein an upper surface of the block layer provided in the concave portion of the charge accumulation layer is lower than the upper surface of the element region.

14. A method of manufacturing a nonvolatile semiconductor memory device, comprising:
forming a tunnel insulating film on a semiconductor substrate;
forming a charge accumulation layer on the tunnel insulating film;
removing the charge accumulation layer, the tunnel insulating film, and an upper portion of the semiconductor substrate, to form a trench extending in a first direction;
forming an element isolation insulating film in the trench to arrange an element region on the semiconductor substrate;
removing an upper portion of the element isolation insulating film to be an upper surface of the element isolation insulating film lower than an upper surface of the element region of the semiconductor substrate;
forming a block layer on the charge accumulation layer and the element isolation insulating film; and
forming a gate electrode on the block layer.

15. The method of manufacturing a nonvolatile semiconductor memory device according to claim 14,
wherein the mask material comprises a laminate film including silicon oxide, amorphous silicon, and silicon nitride.

16. The method of manufacturing nonvolatile semiconductor memory device according to claim 14,
wherein the charge accumulation layer includes a silicon nitride film.
